(19) United States
(12) Patent Application Publication
(10) Pub. No.: US 2013/0120584 A1
(43) Pub. Date: May 16, 2013

(54) SHORT LIGHT PULSE GENERATING DEVICE, TERAHERTZ WAVE GENERATING DEVICE, CAMERA, IMAGING DEVICE, AND MEASURING DEVICE

(71) Applicant: Seiko Epson Corporation, Tokyo (JP)

(72) Inventor: Hitoshi NAKAYAMA, Chino (JP)

(73) Assignee: SEIKO EPSON CORPORATION, Tokyo (JP)

(21) Appl. No.: 13/673,345

(22) Filed: Nov. 9, 2012

(30) Foreign Application Priority Data
Nov. 15, 2011 (JP) 2011-249420

(51) Int. Cl. H01S 5/00; H04N 5/33; G01N 21/17

(52) U.S. Cl. CPC H01S 5/0057; G01N 21/17; H04N 5/33
USPC 348/164; 359/337.5; 250/338.1

(57) ABSTRACT

A short light pulse generating device includes a light pulse generating part, a first pulse compressing part, a second pulse compressing part, and an amplifying part. The light pulse generating part is configured to generate light pulses, the light pulse generating part being a super luminescent diode. The first pulse compressing part is configured to perform pulse compression based on saturable absorption on the light pulses generated by the light pulse generating part. The second pulse compressing part is configured to perform pulse compression based on group velocity dispersion compensation on the light pulses that underwent the pulse compression by the first pulse compressing part. The amplifying part is provided between the first pulse compressing part and the second pulse compressing part, and configured to amplify the light pulses that underwent the pulse compression by the first pulse compressing part.

### CROSS-REFERENCE TO RELATED APPLICATIONS

This application claims priority to Japanese Patent Application No. 2011-249420 filed on Nov. 15, 2011. The entire disclosure of Japanese Patent Application No. 2011-249420 is hereby incorporated herein by reference.

### BACKGROUND

1. Technical Region

The present invention relates to a short light pulse generating device, and a terahertz wave generating device, camera, imaging device, and measuring device equipped with a short light pulse generating device.

2. Related Art

In recent years, attention has been devoted to terahertz waves, which are electromagnetic waves with frequencies of 100 GHz or greater and 30 THz or less. Terahertz waves can be used in various forms of measurement and non-destructive testing such as imaging and spectrometry.

An example of a terahertz wave generating device is a photoconductive antenna terahertz wave generating device. This terahertz wave generating device has a light pulse generating part which generates light pulses having pulse widths at the approximately sub pico second level (several hundred femtoseconds) and an antenna that generates terahertz waves by irradiating light pulses generated by the light pulse generating part. As a light pulse generating part that generates light pulses of pulse widths at the sub pico second level, a femtosecond fiber laser, a titanium sapphire laser or the like is used, but it is also possible to use a short pulse semiconductor laser component or the like to make the terahertz wave generating device even more compact (see Japanese Patent No. 3328881 and Japanese Patent No. 3014039).

### SUMMARY

However, with the semiconductor short pulse laser components noted in Japanese Patent No. 3328881 and Japanese Patent No. 3014039, when using an edge emitting type semiconductor laser component using a cleavage surface as a reflecting mirror as the light pulse generating part, it is necessary to separate the light pulse generating part and the pulse compressing part, so optical coupling is performed using an optical product such as a lens or the like, but the cross section area of the optical waveguide of the pulse compressing part is extremely narrow, and optical alignment is extremely difficult, so the optical coupling efficiency of the semiconductor laser component and the pulse compressing part is poor. As a result, there is an increase in manhours required for optical alignment, and the need further arises to increase the light output of the light pulse generating part to obtain the required light output, so there is a problem of increased power consumption.

Also, when using a distributed feedback semiconductor laser component as the light pulse generating part, it is not necessary to separate the light pulse generating part and the pulse compressing part, so it is possible to make the light pulse generating part and the pulse compressing part as an integrated unit, which improves the coupling efficiency, but it is necessary to selectively produce a diffraction grating within the semiconductor laser component, resulting in problems of the manufacturing process becoming complex, yield decreasing, and the manufacturing cost rising.

The present invention was created to address at least part of the problems described above, and it can be realized as the modes or aspects noted below.

A short light pulse generating device according to one aspect of the present invention includes a light pulse generating part, a first pulse compressing part, a second pulse compressing part, and an amplifying part. The light pulse generating part is configured to generate light pulses, the light pulse generating part being a super luminescent diode. The first pulse compressing part is configured to perform pulse compression based on saturable absorption on the light pulses generated by the light pulse generating part. The second pulse compressing part is configured to perform pulse compression based on group velocity dispersion compensation on the light pulses that underwent the pulse compression by the first pulse compressing part. The amplifying part is provided between the first pulse compressing part and the second pulse compressing part, and configured to amplify the light pulses that underwent the pulse compression by the first pulse compressing part.

With this aspect, since the light pulse generating part is a super luminescent diode (hereafter called SLD), a resonator structure is not needed, it is not necessary to separate the light pulse generating part and the pulse compressing part, and it is possible to form the light pulse generating part and the pulse compressing part as an integrated unit without requiring complicated manufacturing processes.

Therefore, it is possible to provide a short light pulse generating device for which the light utilization efficiency is high, and a complicated manufacturing process is not required.

A short light pulse generating device according to another aspect of the present invention includes a light pulse generating part, a first pulse compressing part, a second pulse compressing part, and an amplifying part. The light pulse generating part is configured to generate light pulses, the light pulse generating part being a super luminescent diode. The first pulse compressing part is configured to perform pulse compression based on saturable absorption on the light pulses generated by the light pulse generating part. The second pulse compressing part is configured to perform pulse compression based on group velocity dispersion compensation on the light pulses that underwent the pulse compression by the first pulse compressing part. The amplifying part is provided between the light pulse generating part and the first pulse compressing part, and configured to amplify the light pulses generated by the light pulse generating part.

With this aspect, since the light pulse generating part is a super luminescent diode, a resonator structure is not needed, it is not necessary to separate the light pulse generating part and the pulse compressing part, and it is possible to form the light pulse generating part and the pulse compressing part as an integrated unit without requiring complicated manufacturing processes.

Therefore, it is possible to provide a short light pulse generating device for which the light utilization efficiency is high, and a complicated manufacturing process is not required.

With the short light pulse generating device of the aforementioned aspect, the first pulse compressing part or the amplifying part preferably has a first waveguide extending in a first direction, a second waveguide extending in a second direction different from the first direction, and a connecting waveguide that connects the first waveguide and the second waveguide.

With this aspect, the waveguide is bent, so it is possible to make this more compact than with a straight line waveguide.

The short light pulse generating device according to the aforementioned aspect preferably has a reflective film that reflects the light pulses on the connecting waveguide.

With this aspect, since there is a reflective film, it is possible to reduce the light loss due to the connecting waveguide (specifically, the bent part of the waveguide), and it is possible to prevent loss of the light volume.

The short light pulse generating device according the aforementioned aspect is preferably equipped with a plurality of unitary units having a light pulse generating part, a first pulse compressing part, a second pulse compressing part, and an amplifying part.

With this aspect, by synthesizing the pulses emitted from each unitary unit, it is possible to generate high output short light pulses.

A terahertz wave generating device according to another aspect is equipped with the short light pulse generating device of the aforementioned aspect, and an antenna on which short light pulses emitted from the short light pulse generating device are irradiated to generate terahertz waves.

With this aspect, it is possible to provide a terahertz wave generating device with high light utilization efficiency and for which complicated manufacturing processes are not required.

A camera according to another aspect is equipped with the short light pulse generating device according the aforementioned aspect, an antenna on which short light pulses emitted from the short light pulse generating device are irradiated to generate terahertz waves, and a terahertz wave detecting device configured to detect the terahertz waves emitted from the antenna and transmitted through an object or reflected by the object.

With this aspect, it is possible to provide a camera with a high light utilization efficiency, and for which complicated manufacturing processes are not required.

An imaging device according to another aspect is equipped with the short light pulse generating device according to the aforementioned aspect, an antenna on which short light pulses emitted from the short light pulse generating device are irradiated to generate terahertz waves, a terahertz wave detecting device configured to detect the terahertz waves emitted from the antenna and transmitted through an object or reflected by the object, and an image generating unit configured to generate an image of the object based on the detection results of the terahertz wave detecting device.

With this aspect, it is possible to provide an imaging device with high light utilization efficiency, and for which complicated manufacturing processes are not required.

A measuring device according to another aspect is equipped with the short light pulse generating device of the aforementioned aspect, an antenna on which short light pulses emitted from the short light pulse generating device are irradiated to generate terahertz waves, a terahertz wave detecting device configured to detect the terahertz waves emitted from the antenna and transmitted through the object or reflected by the object, and a measuring unit configured to measure the object based on the detection results of the terahertz wave detecting device.

With this aspect, it is possible to provide a measuring device with high light utilization efficiency, and for which complicated manufacturing processes are not required.

### BRIEF DESCRIPTION OF THE DRAWINGS

Referring now to the attached drawings which form a part of this original disclosure:

FIG. 1 is a perspective view showing the constitution of the semiconductor short pulse generating device of the first embodiment.

FIG. 2 is a cross section view of line A-A in FIG. 1.

FIG. 3 is a cross section view of line B-B in FIG. 1.

FIG. 4 is a perspective view showing the constitution of the semiconductor short pulse generating device of the second embodiment.

FIG. 5 is a plan view of the constitution of the semiconductor short pulse generating device of the third embodiment.

FIG. 6 is a plan view of the constitution of the semiconductor short pulse generating device of the fourth embodiment.

FIG. 7 is a plan view of the constitution of the semiconductor short pulse generating device of the fifth embodiment.

FIG. 8 is a pattern diagram of an embodiment of a terahertz wave generating device.

FIG. 9 is a block view of an embodiment of an imaging device.

FIG. 10 is a plan view of the terahertz wave detecting device in FIG. 9.

FIG. 11 is a graph showing the spectrum of the terahertz band of an object.

FIG. 12 is a drawing showing the distribution of substances A, B, and C of the object.

FIG. 13 is a block diagram of an embodiment of a measuring device.

FIG. 14 is a block diagram of an embodiment of a camera.

### DETAILED DESCRIPTION OF EXEMPLARY EMBODIMENTS

Embodiments of the present invention will be described while referring to the drawings. With each drawing below, to make each layer and each member a recognizable size, the scale of the layers and the members has been modified from the actual state.

### First Embodiment

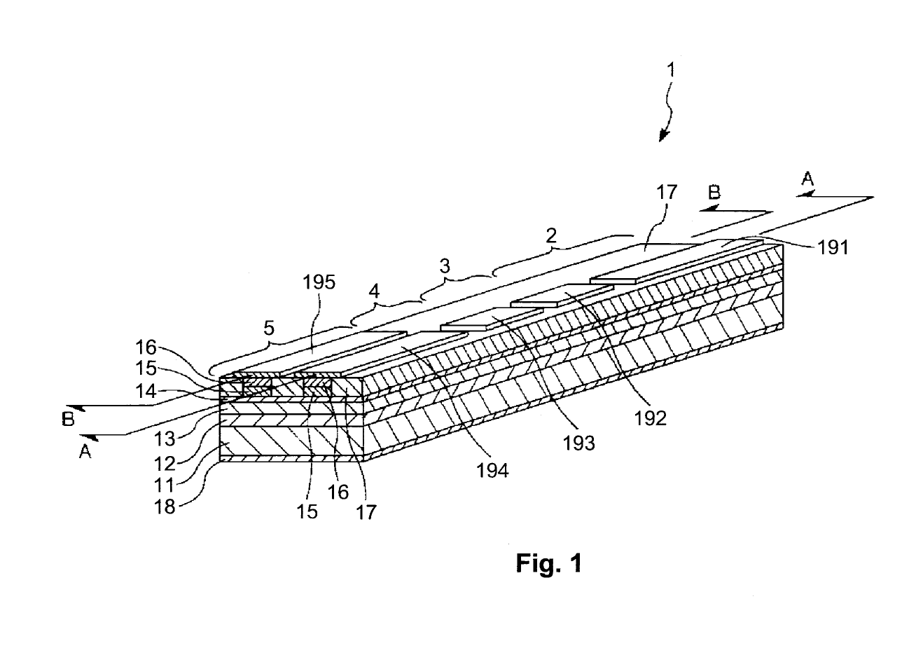

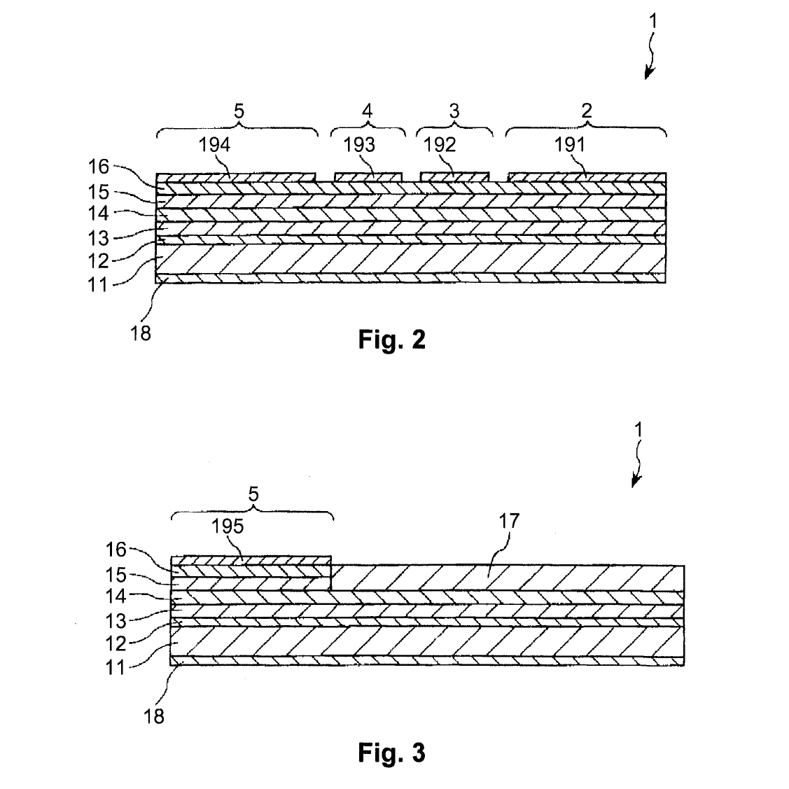

FIG. 1 is a perspective view of the semiconductor short pulse generating device of the present invention. FIG. 2 is a cross section view of line A-A in FIG. 1. FIG. 3 is a cross section view of line B-B in FIG. 1.

As shown in FIG. 1 to FIG. 3, the semiconductor short pulse generating device (short light pulse generating device) 1 has a light pulse generating part 2 for generating light pulses, a first pulse compressing part 3 for performing pulse compression on the light pulses generated by the light pulse generating part 2, a second pulse compressing part 5 for performing pulse compression on the light pulses for which pulse compression was done by the first pulse compressing part 3, and an amplifying part 4 for amplifying light pulses.

The amplifying part 4 is provided at the front part of the first pulse compressing part 3, or between the first pulse compressing part 3 and the second pulse compressing part 5, but with the constitution in the drawings, the amplifying part 4 is provided between the first pulse compressing part 3 and the second pulse compressing part 5. As a result, the light pulses for which pulse compression was done by the first pulse compressing part 3 are amplified by the amplifying part 4, and the light pulses amplified by the amplifying part undergo pulse compression by the second pulse compressing part 5.

Also, the pulse width (half-value width) of the light pulses (short light pulses) emitted from the semiconductor short pulse generating device 1 is not particularly restricted, but is preferably 10 femtoseconds or greater and 800 femtoseconds or less. Also, an SLD is used for the light pulse generating part 2.

Also, the first pulse compressing part 3 performs pulse compression based on saturable absorption. Specifically, the first pulse compressing part 3 has a saturable absorber, and using that saturable absorber, light pulses are compressed and pulse width is decreased.

Also, the second pulse compressing part 5 is an item that performs pulse compression based on group velocity dispersion compensation. Specifically, the second pulse compressing part 5 has a group velocity dispersion compensation medium, with this embodiment a coupled waveguide structure, and using that coupled waveguide structure, light pulses are compressed and pulse width is decreased.

Also, the light pulse generating part 2, the first pulse compressing part 3, the amplifying part 4, and the second pulse compressing part 5 of the semiconductor short pulse generating device 1 are formed as an integral unit, specifically, are integrated on the same substrate.

In specific terms, the semiconductor short pulse generating device 1 has a substrate 11 which is a semiconductor substrate, a cladding layer 12 provided on one surface of the substrate 11, an active layer 13 provided on the cladding layer 12, a waveguide structure processing etching stop layer 14 provided on the active layer 13, a cladding layer 15 provided on the waveguide structure processing etching stop layer 14, a contact layer 16 provided on the cladding layer 15, an insulating layer 17 provided on the waveguide structure processing etching stop layer 14, an electrode 18 provided on the other surface of the substrate 11, and cladding layer 15-side electrodes 191, 192, 193, 194, and 195 provided on the contact layer 16 and insulating layer 17 surface. The waveguide structuring processing etching stop layer is not restricted to being directly above the active layer, and for example may also be provided inside the cladding layer.

The structural materials of each part are not particularly restricted, but an example for the substrate 11 and the contact layer 15 is GaAs or the like. Also, an example for the cladding layers 12 and 15, and the waveguide structure processing etching stop layer 14 includes AlGaAs or the like. Also, for the active layer 13, an example is a structure using a quantum effect called a multiple quantum well or the like. In specific terms, an example of the active layer 13 is an item with a structure called a distributed index of refraction multiple quantum well structure with multiple quantum wells or the like made by alternately providing a plurality of well layers (GaAs well layers) and barrier layers (AlGaAs barrier layers) or the like.

With the constitution in the drawing, the waveguide of the semiconductor short pulse generating device 1 is constituted from the cladding layer 12, the active layer 13, the waveguide structure processing etching stop layer 14, and the cladding layer 15. Also, the cladding layer 15 is provided in a shape corresponding to the waveguide, only on the top part of the waveguide. Also, the cladding layer 15 is formed by removal of the unnecessary parts by etching. Depending on the manufacturing method, it is possible to omit the waveguide structure processing etching stop layer 14.

Also, two each of the cladding layer 15 and the contact layer 16 are provided. One of the cladding layer 15 and the contact layer 16 constitute the light pulse generating part 2, the first pulse compressing part 3, the amplifying part 4, and part of the second pulse compressing part 5, and are provided sequentially, and the other cladding layer 15 and contact layer 16 constitute part of the second pulse compressing part 5. Specifically, one pair of cladding layers 15 and one pair of contact layers 16 are provided on the second pulse compressing part 5.

Also, the electrode 191 is provided so as to correspond to the cladding layer 15 of the light pulse generating part 2, the electrode 192 is provided so as to correspond to the cladding layer 15 of the first pulse compressing part 3, the electrode 193 is provided so as to correspond to the cladding layer 15 of the amplifying part 4, and the electrodes 194 and 195 are provided so as to respectively correspond to the two cladding layers 15 of the second pulse compressing part 5. The electrode 18 is a shared electrode of the light pulse generating part 2, the first pulse compressing part 3, the amplifying part 4, and the second pulse compressing part 5. Then, the pair of electrodes of the light pulse generating part 2 is constituted by the electrode 18 and the electrode 191, the pair of electrodes of the first pulse compressing part 3 is constituted by the electrode 18 and the electrode 192, the pair of electrodes of the amplifying part 4 is constituted by the electrode 18 and the electrode 193, and the two pairs of electrodes of the second pulse compressing part 5 are constituted by the electrode 18 and electrode 194 and the electrode 18 and electrode 195.

The overall shape of the semiconductor short pulse generating device 1 is a rectangular solid in the drawing, but naturally it is not restricted to this.

Also, the dimensions of the semiconductor short pulse generating device 1 are not particularly restricted, but for example can be 1 mm or greater and 10 mm or less×0.5 mm or greater and 5 mm or less×0.1 mm or greater and 1 mm or less.

Next, the operation of the semiconductor short pulse generating device 1 will be described.

With the semiconductor short pulse generating device 1, first, a light pulse is generated with the light pulse generating part 2. This pulse width of the light pulses is greater than the target pulse width. The light pulses generated with the light pulse generating part 2 pass through the waveguide, and are sequentially transmitted through the first pulse compressing part 3, the amplifying part 4, and the second pulse compressing part 5 in that order.

First, with the first pulse compressing part 3, pulse compression based on saturable absorption is performed on the light pulses, and the pulse width of the light pulses is decreased. Next, with the amplifying part 4, the light pulses are amplified. Finally, with the second pulse compressing part 5, pulse compression based on group velocity dispersion compensation is performed, and the pulse width of the light pulses is further decreased. In this way, light pulses of the target pulse width are generated, and these are emitted from the second pulse compressing part 5.

As described above, with the semiconductor short pulse generating device 1, an SLD is used for the light pulse generating part 2, so a resonator structure is unnecessary, it is not necessary to separate the light pulse generating part 2 and the pulse compressing parts 3 and 5, and it is possible to form the light pulse generating part 2 and the pulse compressing parts 3 and 5 as an integral unit.

### Second Embodiment

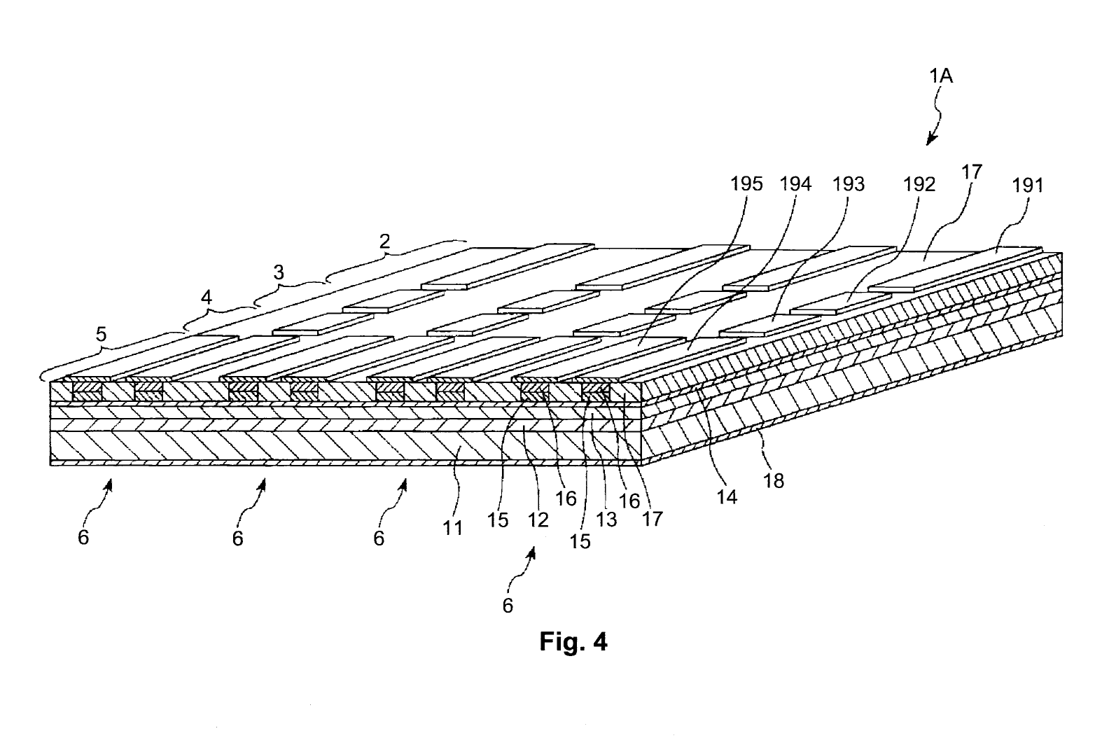

FIG. 4 is a perspective view showing a semiconductor short pulse generating device of the second embodiment of the semiconductor short pulse generating device of the present invention.

Following, for the second embodiment, the description focuses on the differences from the previously described first embodiment, and a description will be omitted for items that are the same.

As shown in FIG. 4, with the semiconductor short pulse generating device 1A of the second embodiment, a plurality of unitary units 6 are equipped, with the light pulse generating part 2, the first pulse compressing part 3, the amplifying part 4, and the second pulse compressing part 5 as unitary units 6, and these unitary units 6 are provided in parallel, specifically, put into array form. Each unitary unit 6 respectively correlates to the semiconductor short pulse generating device 1 of the first embodiment.

With the configuration in the drawing, there are four unitary units 6, but the number is not limited to this, and can also be two, three, or five or more.

As described above, with the semiconductor short pulse generating device 1A, by synthesizing the pulses emitted from each unitary unit 6, it is possible to generate high output short pulses.

This second embodiment can also be applied to the third embodiment, fourth embodiment, and fifth embodiment described later.

### Third Embodiment

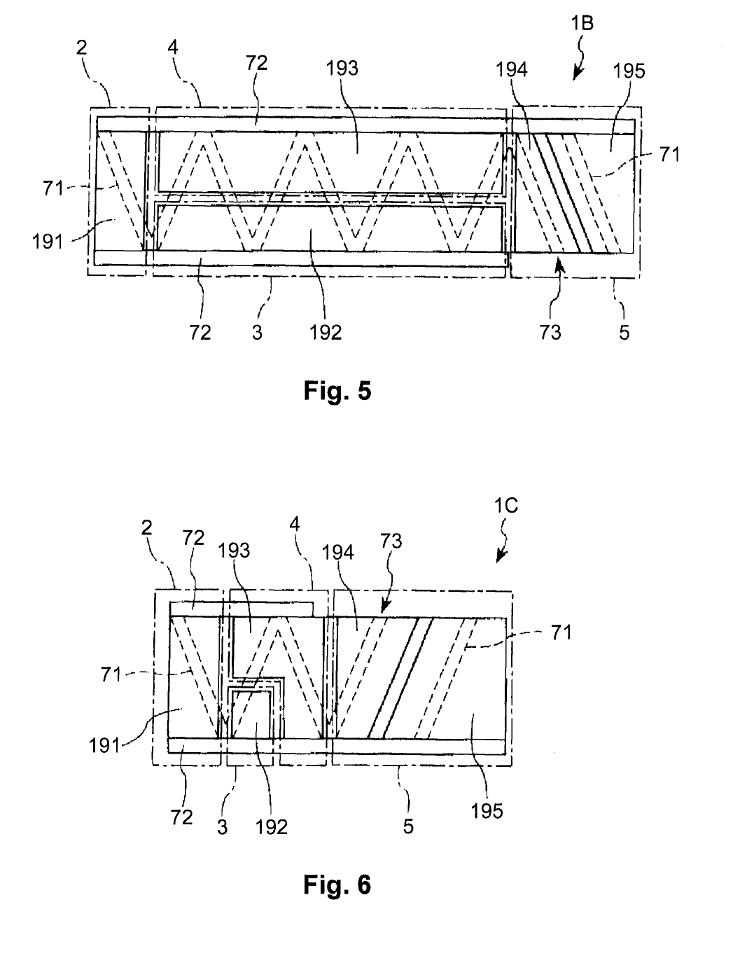

FIG. 5 is a plan view of the third embodiment of the semiconductor short pulse generating device of the present invention. With FIG. 5, the waveguide 71 is shown with a dashed line, and the light pulse generating part 2, the first pulse compressing part 3, the amplifying part 4, and the second pulse compressing part 5 are respectively shown enclosed by dot-dashed lines.

Following, the third embodiment will be described with a focus on the differences from the first embodiment, and a description will be omitted of items that are the same.

As shown in FIG. 5, with the semiconductor short pulse generating device 1B of the third embodiment, the waveguide 71 is alternately bent a plurality of times. Specifically, the waveguide 71 is formed in a zigzag. To say this another way, it has a first waveguide extending in a first direction, a second waveguide extending in a second direction, and a connecting waveguide connecting the first waveguide and the second waveguide.

Also, the first pulse compressing part 3 is positioned at the bottom side in FIG. 5, and the amplifying part 4 is positioned at the top side in FIG. 5. Then, with the first pulse compressing part 3 and the amplifying part 4, the respective waveguides 71 are bent a plurality of times. Also, at the boundary of the light pulse generating part 2 and the first pulse compressing part 3, and the boundary of the amplifying part 4 and the second pulse compressing part 5, the respective waveguides 71 are bent one time.

Also, the semiconductor short pulse generating device 1B has a reflective film 72 that reflects light pulses on the bent part of the waveguide 71 (specifically, the connecting waveguide). This reflective film 72 is respectively provided on the side surface of one pair of the semiconductor short pulse generating devices 1B. With this reflective film 72, it is possible to reflect a light pulse such that the light pulse advances along the waveguide 71.

Note that the reflective film 72 is not provided on the light pulse emission unit 73 of the semiconductor short pulse generating device 1 B. Also, an antireflection film (not illustrated) may be provided on the emission unit 73.

With this semiconductor short pulse generating device 1 B, the waveguide 71 is bent a plurality of times, so the optical path length, specifically, the straight line distance of the waveguides 71 can be made longer, and as a result, it is possible to shorten the length of the direction in which the light pulses of the semiconductor short pulse generating device 1B advance, allowing the size to be even more compact.

### Fourth Embodiment

FIG. 6 is a plan view of the fourth embodiment of the semiconductor short pulse generating device of the present invention. In FIG. 6, the waveguides are shown with dashed lines, and the light pulse generating part 2, the first pulse compressing part 3, the amplifying part 4, and the second pulse compressing part 5 are respectively shown enclosed by dot-dashed lines.

Following, for the fourth embodiment, the description will focus on the differences from the previously described third embodiment, and a description will be omitted for items that are the same.

As shown in FIG. 6, with the semiconductor short pulse generating device 1C of the fourth embodiment, the waveguide 71 is alternately bent three times, and with the amplifying part 4, the waveguide 71 is bent only once.

When providing the amplifying part 4 at the front part of the first pulse compressing part 3, with the first pulse compressing part 3, the waveguide 71 is bent only once.

### Fifth Embodiment

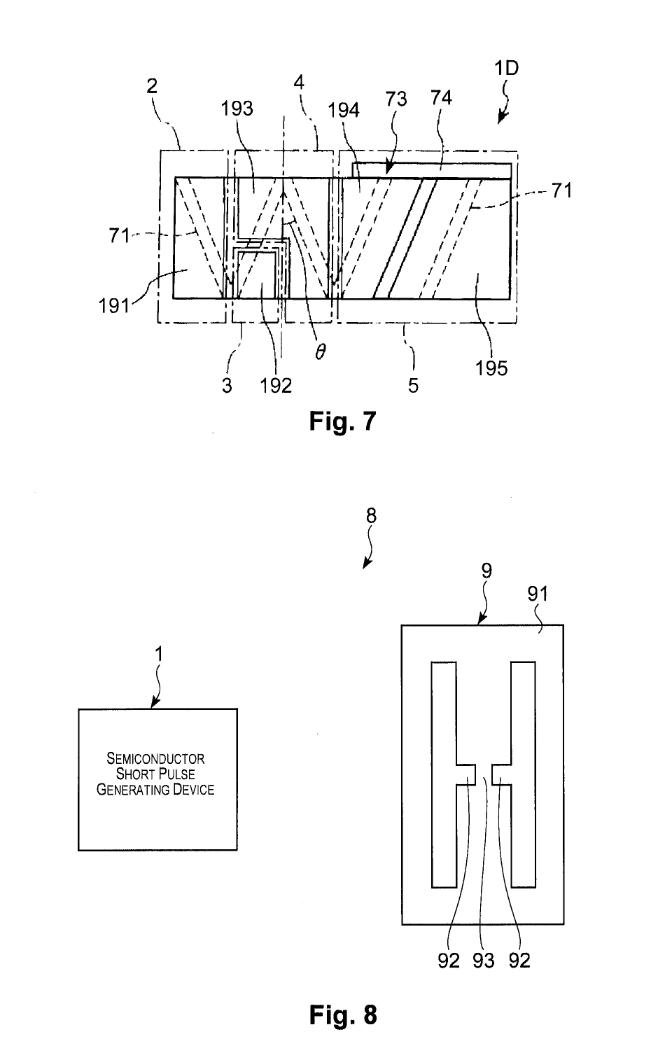

FIG. 7 is a plan view of the fifth embodiment of the semiconductor short pulse generating device of the present invention. In FIG. 7, the waveguides are shown by dashed lines, and the light pulse generating part 2, the first pulse compressing part 3, the amplifying part 4, and the second pulse compressing part 5 are respectively shown enclosed by dot-dashed lines.

Following, the fifth embodiment will be described with a focus on the differences from the previously described fourth embodiment, and a description will be omitted for items that are the same.

As shown in FIG. 7, with the semiconductor short pulse generating device 1D of the fifth embodiment, the reflective film 72 is omitted.

Also, the angle θ shown in FIG. 7 for the bent part of the waveguide 71 is set to be the critical angle or greater. As a result, it is possible to reflect light pulses without providing a reflective film 72 at the bent part of the waveguide 71, and to simplify the constitution.

Also, an antireflection film 74 is provided on the light pulse emission unit 73 of the semiconductor short pulse generating device 1D. As a result, it is possible to have light pulses emitted from the emission unit 73.

Note that the fifth embodiment can also be applied to the third embodiment.

### Embodiment of Terahertz wave Generating Device

FIG. 8 is a drawing schematically showing an embodiment of the terahertz wave generating device of the present invention.

As shown in FIG. 8, the terahertz wave generating device 8 has a semiconductor short pulse generating device 1, and an antenna 9 that generates terahertz waves by irradiating light pulses generated by the semiconductor short pulse generating device 1. The semiconductor short pulse generating device 1 corresponds to the first embodiment and the semiconductor short pulse generating device 1A of the second embodiment.

With this embodiment, the antenna 9 is a dipole shaped photoconductive antenna (PCA), and has a substrate 91 which is a semiconductor substrate, and a pair of electrodes 92 provided on the substrate 91 and arranged facing opposite via a gap 93. When light pulses are irradiated between these electrodes 92, the antenna 9 generates terahertz waves. Terahertz waves are electromagnetic waves for which the frequency is 100 GHz or greater and 30 THz or less, and more particularly electromagnetic waves of 300 GHz or greater and 3 THz or less. Also, the distance between electrodes of the pair of electrodes 92 is not particularly restricted, and is set as appropriate according to various conditions, but is preferably 1 μm or greater and 10 μm or less.

With the semiconductor short pulse generating device 1 of the aforementioned first embodiment, an SLD is used for the light pulse generating part 2, so a resonator structure is unnecessary, and it is possible to make the light pulse generating part and the pulse compressing part an integrated unit without needing to separate the light pulse generating part and the pulse compressing part, and without requiring complicated manufacturing processes.

Therefore, it is possible to provide a terahertz wave generating device 8 for which the light utilization efficiency is high, and complicated manufacturing processes are not necessary.

Also, by preparing a plurality of these terahertz wave generating devices 8, and synthesizing the terahertz waves generated by each terahertz wave generating device 8, it is possible to obtain even higher output terahertz waves.

Also, with the semiconductor short pulse generating device 1A of the aforementioned second embodiment, the semiconductor short pulse generating devices 1 are put in array form, and the output of the terahertz waves generated from one terahertz wave generating device 8 is high, so the number of terahertz wave generating devices 8 used to obtain high output terahertz waves can be relatively low, so it is possible to easily and reliably perform synthesis of terahertz waves.

### Embodiment of Imaging Device

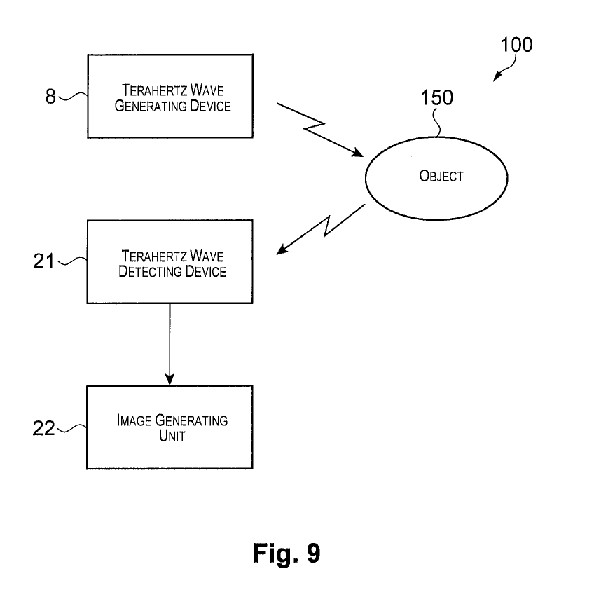

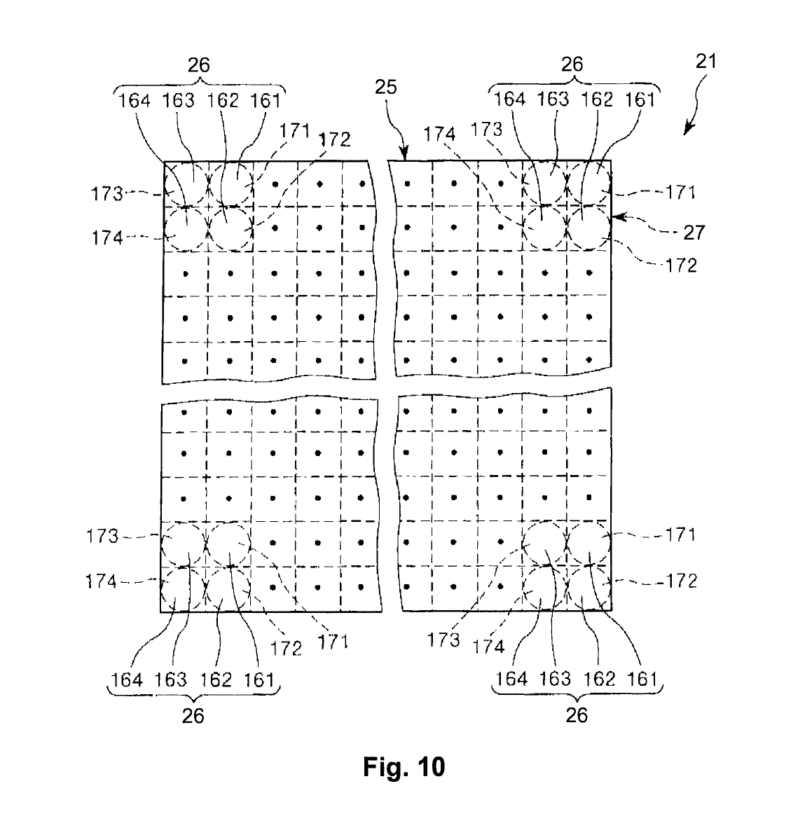

FIG. 9 is a block diagram showing an embodiment of the imaging device of the present invention. FIG. 10 is a plan view showing the terahertz wave detecting device of the imaging device shown in FIG. 9.

As shown in FIG. 9, the imaging device 100 is equipped with a terahertz wave generating device 9 for generating terahertz waves, a wave detecting device 21 for detecting terahertz waves emitted from the terahertz wave generating device 8 and transmitted through or reflected by the object 150, and an image generating unit 22 for generating an image of the object 150, specifically, image data, based on the detection results of the terahertz wave detecting device 21.

As the terahertz wave generating device 8, with this embodiment, the item of the aforementioned terahertz wave generating device is used.

Also, as shown in FIG. 10, as the terahertz wave detecting device 21, for example, an item is used that is equipped with a filter 25 that transmits terahertz waves of target wavelengths, and a detection unit 27 that converts to heat the terahertz waves of the target wavelengths and detects it. Also, as the detection unit 27, for example, an item is used that converts terahertz waves to heat and detects it, specifically, an item that converts terahertz waves to heat, and detects the energy (intensity) of the terahertz waves. As this kind of detection unit, examples include pyroelectric sensors, bolometers and the like. Naturally, the terahertz wave detecting device 21 is not restricted to an item of this constitution.

Also, the filter 25 has a plurality of pixels (unit filter units) 26 arranged two dimensionally. Specifically, the pixels 26 are arranged in matrix form.

Also, the pixels 26 have a plurality of regions that transmit terahertz waves of mutually different wavelengths, specifically, a plurality of regions that have mutually different transmitted terahertz wavelengths (hereafter also called “transmission wavelengths”). With the constitution in the drawing, each pixel 26 has a first region 161, a second region 162, a third region 163, and a fourth region 164.

Also, the detection unit 27 has a first unit detecting unit 171, a second unit detecting unit 172, a third unit detecting unit 173, and a fourth unit detecting unit 174 provided respectively corresponding to the first region 161, second region 162, third region 163, and fourth region 164 of each pixel 26 of the filter 25. Each first unit detecting unit 171, second unit detecting unit 172, third unit detecting unit 173, and fourth unit detecting unit 174 respectively convert to heat and detect terahertz waves that were transmitted through the first region 161, the second region 162, the third region 163, and the fourth region 164 of each pixel 26. As a result, at each respective pixel 26, it is possible to reliably detect the terahertz waves of four target wavelengths.

Next, a usage example of the imaging device 100 will be described.

First, the object 150 that is the subject of spectral imaging is constituted by three substances A, B, and C. The imaging device 100 performs spectral imaging of this object 150. Also, here, as an example, the terahertz wave detecting device 21 detects terahertz waves reflected by the object 150.

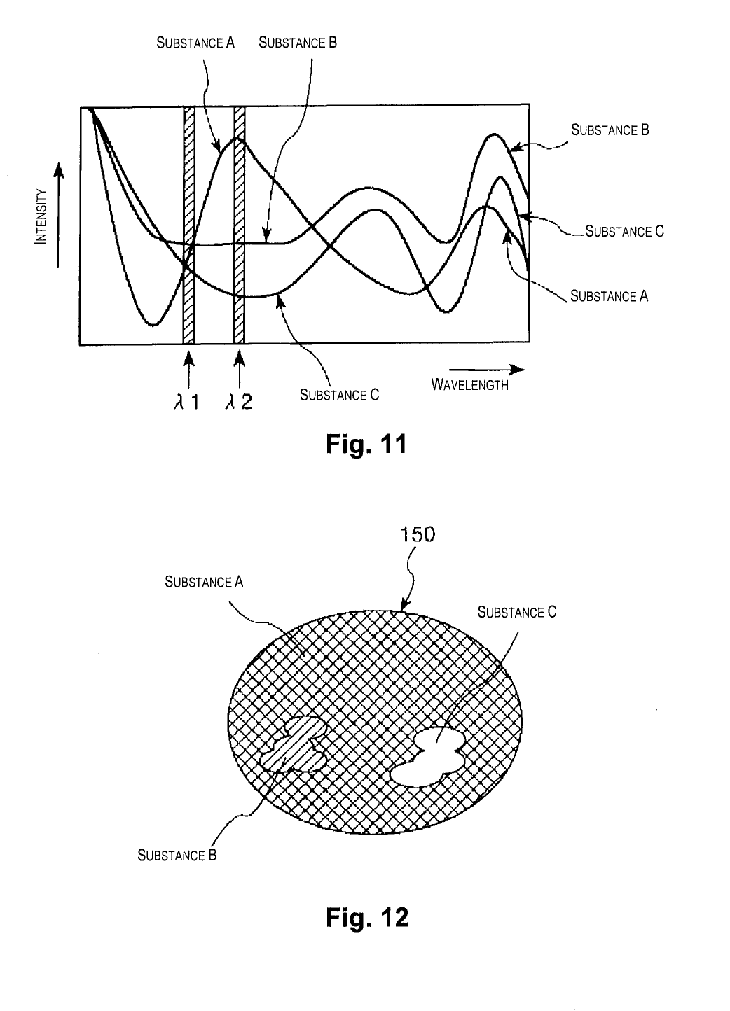

FIG. 11 is a graph showing the spectrum of the terahertz band of the object 150.

With each pixel 26 of the filter 25 of the terahertz wave detecting device 21, a first region 161 and a second region 162 are used.

Also, when the transmission wavelength of the first region 161 is λ1 and the transmission wavelength of the second region 162 is λ2, and the intensity of the wavelength λ1 component of the terahertz wave reflected by the object 150 is α1 and the intensity of the transmission wavelength λ2 component is α2, the transmission wavelength λ1 of the first region 161 and the transmission wavelength λ2 of the second region 162 are set so that the difference (α2−α1) between the intensity α2 and intensity α1 can be clearly mutually distinguished for the substance A, substance B, and substance C.

As shown in FIG. 11, with substance A, the difference between the intensity α2 of the wavelength λ2 component of the terahertz waves reflected by the object 150 and the intensity α1 of the wavelength λ1 component (α2−α1) is a positive value.

With substance B, the difference between intensity α2 and intensity α1 (α2−α1) is zero.

With substance C, the difference between intensity α2 and intensity α1 (α2−α1) is a negative value.

With the imaging device 100, when performing spectral imaging of the object 150, first, terahertz waves are generated by the terahertz wave generating device 8, and those terahertz waves are irradiated on the object 150. Then, the terahertz wave detecting device 21 detects the terahertz waves reflected by the object 150. These detection results are sent to the image generating unit 22. The detection of irradiation of terahertz waves on the object 150 and terahertz waves reflected by the object 150 is performed for the overall object 150.

The image generating unit 22 finds the difference (α2−α1) between the intensity α2 of the wavelength λ2 component of the terahertz waves transmitted through the second region 162 of the filter 25 and the intensity al of the wavelength λ1 component of the terahertz waves transmitted through the first region 161 based on the detection results. Then, of the object 150, sites for which the difference is a positive value are determined and specified as being substance A, sites for which the difference is zero as substance B, and sites for which the difference is a negative value as substance C.

As shown in FIG. 12, the image generating unit 22 creates image data of an image showing the distribution of the substances A, B and C of the object 150. This image data is sent to a monitor (not illustrated) from the image generating unit 22, and an image showing the distribution of the substance A, substance B, and substance C of the object 150 is displayed on the monitor. In this case, for example, color coded display is done so that the region in which substance A of the object 150 is distributed is shown as black, the region in which substance B is distributed is shown as gray, and the region in which substance C is distributed is shown as white. With this imaging device 100, as described above, it is possible to identify each substance constituting the object 150 and to simultaneously perform distribution measurement of each substance.

The application of the imaging device 100 is not limited to the item described above, and for example, it is possible to irradiate terahertz waves on a person, to detect terahertz waves transmitted or reflected by that person, and by performing processing at the image generating unit 22, it is possible to determine whether that person is holding a gun, knife, illegal drugs or the like.

### Embodiment of Measuring device

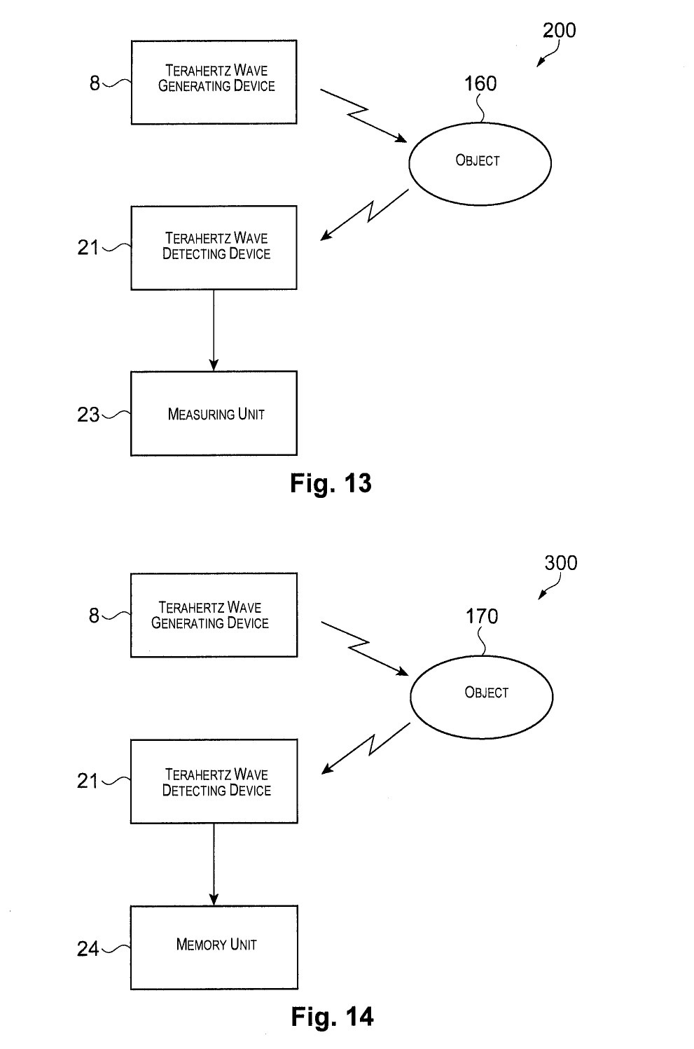

FIG. 13 is a block diagram showing an embodiment of the measuring device of the present invention.

Following, the description of the embodiment of the measuring device will focus on the differences from the previously described embodiment of the imaging device, and a description will be omitted for items that are the same.

As shown in FIG. 13, the measuring device 200 is equipped with a terahertz wave generating device 8 for generating terahertz waves, a terahertz wave detecting device 21 for detecting terahertz waves emitted from the terahertz wave generating device 8 and transmitted through or reflected by the object 160, and a measuring unit 23 for measuring the object 160 based on the detection results of the terahertz wave detecting device 21.

Next, a use example of the measuring device 200 will be described.

With the measuring device 200, when performing spectroscopic measurement of the object 160, first, terahertz waves are generated by the terahertz wave generating device 8, and those terahertz waves are irradiated on the object 160. Then, the terahertz waves transmitted by or reflected by the object 160 are detected by the terahertz wave detecting device 21. These detection results are sent to the measuring unit 23. Irradiation of the terahertz waves on the object 160 and detection of the terahertz waves transmitted by or reflected by the object 160 are performed for the overall object 160.

With the measuring unit 23, from the detection results, the respective intensities of the terahertz waves that were transmitted through the first region 161, the second region 162, the third region 163, and the fourth region 164 of the filter 25 are found out, and analysis or the like of the object 160 components and their distribution is performed.

### Embodiment of Camera

FIG. 14 is a block diagram showing the embodiment of the camera of the present invention.

Following, the description of the embodiment of the camera will focus on the differences from the previously described embodiment of the image device, and a description will be omitted for items that are the same.

As shown in FIG. 14, the camera 300 is equipped with a terahertz wave generating device 8 for generating terahertz waves, and a terahertz wave detecting device 21 for detecting terahertz waves emitted from the terahertz wave generating device 8 and transmitted by or reflected by the object 170.

Next, a use example of the camera 300 will be described.

With the camera 300, when taking an image of the object 170, first, terahertz waves are generated by the terahertz wave generating device 8, and those terahertz waves are irradiated on the object 170. Then, the terahertz waves transmitted by or reflected by the object 170 are detected by the terahertz wave detecting device 21. The detection results are sent to and stored in the memory unit 24. Detection of irradiation of the terahertz waves on the object 170 and of the terahertz waves transmitted through or reflected by the object 170 is performed on the overall object 170. The detection results can also be sent to an external device such as a personal computer or the like. With the personal computer, it is possible to perform various processes based on the detection results.

Above, the terahertz wave generating device 8, the camera 300, the imaging device 100, and the measuring device 200 of the present invention were described based on the embodiments in the drawings, but the present invention is not limited to this, and the constitution of each part can be replaced with an item of any constitution having the same functions. It is also possible to add any other constituent materials to the present invention.

Also, the present invention can be a combination of any two or more of the constitutions (features) of each of the aforementioned embodiments.

### General Interpretation of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A short light pulse generating device comprising:
a light pulse generating part configured to generate light pulses, the light pulse generating part being a super luminescent diode;
a first pulse compressing part configured to perform pulse compression based on saturable absorption on the light pulses generated by the light pulse generating part;
a second pulse compressing part configured to perform pulse compression based on group velocity dispersion compensation on the light pulses that underwent the pulse compression by the first pulse compressing part; and
an amplifying part provided between the first pulse compressing part and the second pulse compressing part, and configured to amplify the light pulses that underwent the pulse compression by the first pulse compressing part.

2. The short light pulse generating device according to claim 1, wherein
the first pulse compressing part includes a first waveguide extending in a first direction, a second waveguide extending in a second direction different from the first direction, and a connecting waveguide that connects the first waveguide and the second waveguide.

3. The short light pulse generating device according to claim 2, wherein
the first pulse compressing part includes a reflective film disposed on the connecting waveguide, the reflective film being configured to reflect the light pulses.

4. The short light pulse generating device according to claim 1, wherein
the amplifying part includes a first waveguide extending in a first direction, a second waveguide extending in a second direction different from the first direction, and a connecting waveguide that connects the first waveguide and the second waveguide.

5. The short light pulse generating device according to claim 4, wherein
the amplifying part includes a reflective film disposed on the connecting waveguide, the reflective film being configured to reflect the light pulses.

6. The short light pulse generating device according to claim 1, wherein
the short light pulse generating device includes a plurality of unitary units having the light pulse generating part, the first pulse compressing part, the second pulse compressing part, and the amplifying part.

7. A short light pulse generating device comprising:
a light pulse generating part configured to generate light pulses, the light pulse generating part being a super luminescent diode;
a first pulse compressing part configured to perform pulse compression based on saturable absorption on the light pulses generated by the light pulse generating part;
a second pulse compressing part configured to perform pulse compression based on group velocity dispersion compensation on the light pulses that underwent the pulse compression was by the first pulse compressing part; and
an amplifying part provided between the light pulse generating part and the first pulse compressing part, and configured to amplify the light pulses generated by the light pulse generating part.

8. The short light pulse generating device according to claim 7, wherein
the first pulse compressing part includes a first waveguide extending in a first direction, a second waveguide extending in a second direction different from the first direction, and a connecting waveguide that connects the first waveguide and the second waveguide.

9. The short light pulse generating device according to claim 8, wherein
the first pulse compressing part includes a reflective film disposed on the connecting waveguide, the reflective film being configured to reflect the light pulses.

10. The short light pulse generating device according to claim 7, wherein
the amplifying part includes a first waveguide extending in a first direction, a second waveguide extending in a second direction different from the first direction, and a connecting waveguide that connects the first waveguide and the second waveguide.

11. The short light pulse generating device according to claim 10, wherein
the amplifying part includes a reflective film disposed on the connecting waveguide, the reflective film being configured to reflect the light pulses.

12. The short light pulse generating device according to claim 7, wherein
the short light pulse generating device includes a plurality of unitary units having the light pulse generating part, the first pulse compressing part, the second pulse compressing part, and the amplifying part.

13. A terahertz wave generating device comprising:
the short light pulse generating device according to claim 1; and
an antenna on which short light pulses emitted from the short light pulse generating device are irradiated to generate terahertz waves.

14. A terahertz wave generating device comprising:
the short light pulse generating device according to claim 7; and
an antenna on which short light pulses emitted from the short light pulse generating device are irradiated to generate terahertz waves.

15. A camera comprising:
the short light pulse generating device according to claim 1;
an antenna on which short light pulses emitted from the short light pulse generating device are irradiated to generate terahertz waves; and
a terahertz wave detecting device configured to detect the terahertz waves emitted from the antenna and transmitted through an object or reflected by the object.

16. A camera comprising:
the short light pulse generating device according to claim 7;
an antenna on which short light pulses emitted from the short light pulse generating device are irradiated to generate terahertz waves; and
a terahertz wave detecting device configured to detect the terahertz waves emitted from the antenna and transmitted through an object or reflected by the object.

17. An imaging device comprising:
the short light pulse generating device according to claim 1;
an antenna on which short light pulses emitted from the short light pulse generating device are irradiated to generate terahertz waves;
a terahertz wave detecting device configured to detect the terahertz waves emitted from the antenna and transmitted through an object or reflected by the object; and
an image generating unit configured to generate an image of the object based on detection results of the terahertz wave detecting device.

18. An imaging device comprising:
the short light pulse generating device according to claim 7;
an antenna on which short light pulses emitted from the short light pulse generating device are irradiated to generate terahertz waves;
a terahertz wave detecting device configured to detect the terahertz waves emitted from the antenna and transmitted through an object or reflected by the object; and
an image generating unit configured to generate an image of the object based on detection results of the terahertz wave detecting device.

19. A measuring device comprising:
the short light pulse generating device according to claim 1;
an antenna on which short light pulses emitted from the short light pulse generating device are irradiated to generate terahertz waves;
a terahertz wave detecting device configured to detect the terahertz waves emitted from the antenna and transmitted through an object or reflected by the object; and
a measuring unit configured to measure the object based on detection results of the terahertz wave detecting device.

20. A measuring device comprising:
the short light pulse generating device according to claim 7;
an antenna on which short light pulses emitted from the short light pulse generating device are irradiated to generate terahertz waves;
a terahertz wave detecting device configured to detect the terahertz waves emitted from the antenna and transmitted through an object or reflected by the object; and
a measuring unit configured to measure the object based on detection results of the terahertz wave detecting device.
